(19) United States
(12) Patent Application Publication
(10) Pub. No.: US 2026/0223578 A1
(43) Pub. Date: Jul. 30, 2026

(54) Display Device and Method of Manufacturing the Same

(71) Applicant: LG Display Co., Ltd., Seoul (KR)

(72) Inventors: Young Ki Song, Paju-si (KR); Kyoung Sang Yoon, Paju-si (KR)

(21) Appl. No.: 19/415,099

(22) Filed: Dec. 10, 2025

(30) Foreign Application Priority Data
Jan. 24, 2025 (KR) 10-2025-0011982

(51) Int. Cl. H10K 59/80; H10K 59/12

(52) U.S. Cl. CPC H10K 59/878; H10K 59/1201; H10K 59/879

(57) ABSTRACT

A display device presented herein includes a display panel including a pixel area configured to generate light and a transmission area configured to transmit light, a drive circuit configured to drive the display panel, and an optical path control layer located at a rear surface of the display panel. The optical path control layer is configured to guide a background of the pixel area or light to the transmission area.

### CROSS-REFERENCE TO RELATED APPLICATION

The present application claims priority to Republic of Korea Patent Application No. 10-2025-0011982, filed on Jan. 24, 2025, which is hereby incorporated by reference in its entirety.

### BACKGROUND

### Field

The present disclosure relates to a display device and a method of manufacturing the same.

### Discussion of the Related Art

As information technology advances, the market for display devices, which are the medium of connection between users and information, is growing. Accordingly, the use of display devices, such as a light emitting display device (LED), a quantum dot display device (QDD), and a liquid crystal display device (LCD), is increasing.

Each of the display devices includes a display panel including subpixels, a drive circuit configured to output a drive signal for driving the display panel, and a power supply configured to generate power to be supplied to the display panel or the drive circuit.

Each of the display devices may be configured such that, when drive signals, such as scan signals and data signals, are supplied to the subpixels formed on the display panel, the selected subpixels transmit light or emit light directly, thereby displaying an image.

### SUMMARY

Embodiments of the present disclosure improve transparency of a display panel (or minimize or at least decrease the reduction in brightness of the display panel) by changing the path of light proceeding to a light-shielding area of the display panel to a transmission area. Embodiments of the present disclosure induce an optical illusion, such as an improved aperture ratio, by allowing a part of the background disposed at a rear surface of the display panel to be visible through the transmission area.

A display device according to one or more embodiments of the present disclosure includes a display panel including a pixel area configured to generate light and a transmission area configured to transmit light, a drive circuit configured to drive the display panel, and an optical path control layer located at a rear surface of the display panel, the optical path control layer being configured to guide a background of the pixel area or light to the transmission area.

The optical path control layer may include a structure configured to change a path of light incident vertically through a rear surface of the pixel area to a diagonal direction and a straight direction and to guide the light to the transmission area.

The optical path control layer may include an incident structure layer disposed so as to correspond to the pixel area and a reflective structure layer disposed so as to correspond to the transmission area.

Each of the incident structure layer and the reflective structure layer may include an equilateral trapezoidal shape in which positions of an upper surface and a lower surface are reversed.

The optical path control layer may include a reflective structure layer disposed so as to correspond to the pixel area and a plurality of incident structure layers located on the reflective structure layer.

The reflective structure layer may include an overlap area overlapping a part of the transmission area.

The reflective structure layer may include a pentagonal shape, and each of the incident structure layers may include a scalene triangular shape.

The reflective structure layer may include an equilateral trapezoidal shape, and each of the incident structure layers may include an isosceles triangular shape.

The optical path control layer may include a structure layer disposed so as to correspond to the pixel area and a transmission portion flat layer disposed so as to correspond to the transmission area.

The structure layer may include a scalene triangular shape.

The structure layer may include a first structure layer and a second structure layer each having a scalene triangular shape.

The first structure layer may include an overlap area overlapping a part of the transmission area.

The height of the first structural layer may be greater than the height of the second structural layer.

A display device according to one or more other embodiments of the present disclosure includes a display panel including a pixel area configured to generate light and a transmission area configured to transmit light, a drive circuit configured to drive the display panel, and an optical path control layer located at a rear surface of the display panel, the optical path control layer being configured to guide a background of the pixel area or light to the transmission area, wherein the optical path control layer includes a structure configured to change a path of light incident vertically through a rear surface of the pixel area and to guide the light to the transmission area.

A method of manufacturing a display device according to one or more embodiments of the present disclosure includes forming a display panel including a pixel area configured to generate light and a transmission area configured to transmit light, forming an optical path control layer configured to guide a background of the pixel area or light to the transmission area, and disposing the optical path control layer at a rear surface of the display panel, wherein the optical path control layer includes a structure configured to change a path of light incident vertically through a rear surface of the pixel area to a diagonal direction and a straight direction and to guide the light to the transmission area.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a schematic view showing a part of the display device according to one or more embodiments of the present disclosure.

FIGS. 2 to 5 are views showing various examples of a pixel that can be implemented in a display panel according to one or more embodiments of the present disclosure.

FIG. 6 is an example view showing a circuit of a subpixel according to one or more embodiments of the present disclosure.

FIG. 7 is an enlarged example view of area K in FIG. 1.

FIG. 8 is a sectional view taken along line I-I′ in FIG. 7.

FIGS. 9 and 10 are views illustrating the characteristics of a display panel according to a first embodiment of the present disclosure.

FIG. 11 is a sectional view showing an optical path control layer according to the first embodiment of the present disclosure.

FIG. 12 is a sectional view showing an optical path control layer according to a second embodiment of the present disclosure.

FIG. 13 is a view illustrating a first optical path control layer shown in FIG. 12 in more detail.

FIG. 14 is a sectional view showing an optical path control layer according to a third embodiment of the present disclosure.

FIG. 15 is a view illustrating a first optical path control layer shown in FIG. 14 in more detail.

FIG. 16 is a sectional view showing an optical path control layer according to a fourth embodiment of the present disclosure.

FIG. 17 is a view illustrating the optical path control layer shown in FIG. 16 in more detail.

FIG. 18 is a sectional view showing an optical path control layer according to a modification of the fourth embodiment of the present disclosure.

FIG. 19 is a simulation result showing reflectivity of a second side control pattern layer for each reference wavelength of incident light according to one or more embodiments of the present disclosure.

FIG. 20 is a simulation result illustrating changes in the optical path due to angle changes in a first side control pattern layer according to a modification of the fourth embodiment of the present disclosure.

### DETAILED DESCRIPTION

The object and technical configuration of the present disclosure and the effects based thereon will be more clearly understood from the following detailed description with reference to the accompanying drawings, which show embodiments of the present disclosure. The embodiments of the present disclosure are provided to enable the technical ideas of the present disclosure to be fully conveyed to those skilled in the art, and the present disclosure may be embodied in other forms without limitation to the embodiments described herein.

In addition, throughout the present disclosure, the same components are denoted by the same reference numerals, and in the drawings, the lengths and thicknesses of layers or areas may be exaggerated for convenience. Furthermore, when a first component is described as being “on” a second component, this includes not only the case in which the first component is located on the second component in direct contact therewith but also the case in which a third component is located between the first and second components.

Terms such as “first” and “second” may be used herein to describe various components, and are used to distinguish one component from another component. However, a first component and a second component may be arbitrarily named according to the convenience of those skilled in the art without departing from the scope of the present disclosure.

The terms used in the present disclosure are provided only to described specific embodiments, and do not limit the present disclosure. Singular forms are intended to include plural forms as well, unless the context clearly indicates otherwise. In the present disclosure, it should be understood that the terms “includes,” “comprises,” “has,” etc. specify the presence of stated features, numbers, steps, operations, elements, components, or combinations thereof, but do not preclude the presence or addition of one or more other features, numbers, steps, operations, elements, components, or combinations thereof.

In addition, all terms, including technical and scientific terms, have the same meanings as those commonly understood by one of ordinary skill in the art to which the present disclosure pertains, unless defined otherwise. Commonly used terms, such as those defined in typical dictionaries, should be interpreted as being consistent with the contextual meaning of the relevant art, and are not to be construed in an ideal or overly formal sense unless expressly defined to the contrary.

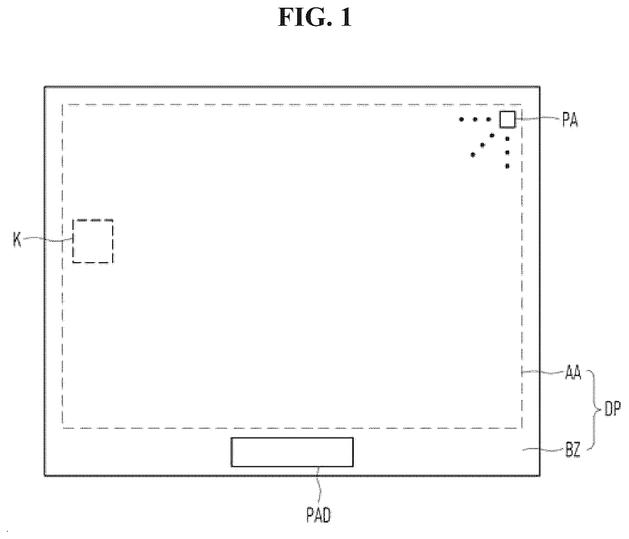

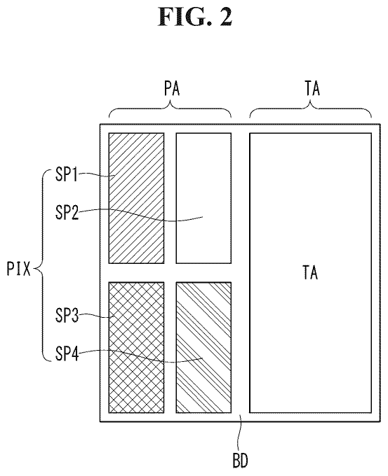

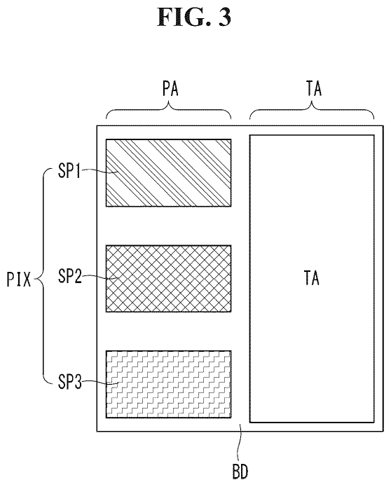

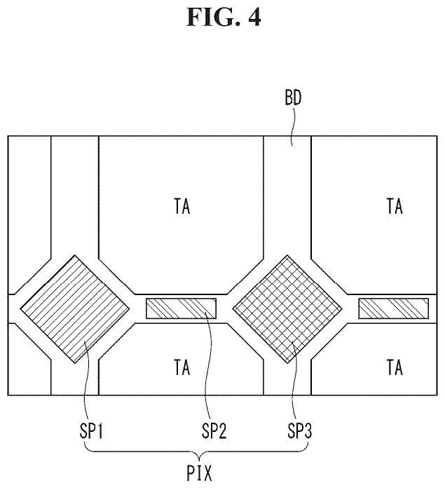

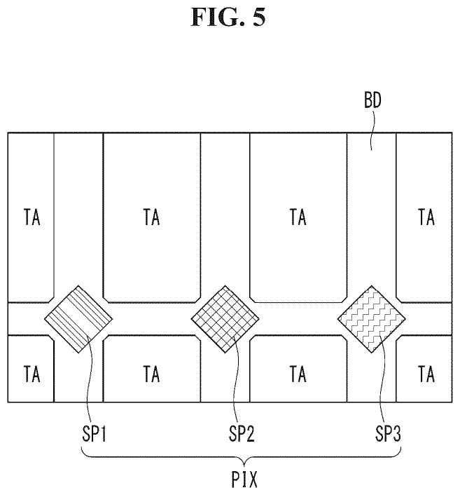

FIG. 1 is a schematic view showing a part of the display device according to one or more embodiments of the present disclosure. FIGS. 2 to 5 are views showing various examples of a pixel that can be implemented in a display panel according to one or more embodiments of the present disclosure.

As shown in FIG. 1, the display device may include a display panel DP. The display panel DP may generate an image to be provided to a user. The display panel DP may include an active area AA and a bezel area BZ located outside the active area.

A pixel area PA may be located in the active area AA, and a pad area PAD may be located in the bezel area BZ. The display panel DP may implement various colors based on pixels included in the pixel area PA. The display panel DP may receive signals and voltage from an external device based on pads included in the pad area PAD.

As shown in FIGS. 2 to 5, a single pixel PIX may include a pixel area PA including at least three subpixels SP1 to SP3 or SP1 to SP4 and at least one transmission area TA. The pixel area PA and the transmission area TA may include a boundary portion configured to partition the pixel area and the transmission area from each other.

The at least three subpixels SP1 to SP3 or SP1 to SP4 may include subpixels configured to emit different colors. For example, the three subpixels SP1 to SP3 may include red, green, and blue subpixels, and the four subpixels SP1 to SP4 may include red, green, blue, and white subpixels.

Meanwhile, FIGS. 2 to 5 show the at least three subpixels SP1 to SP3 or SP1 to SP4 have a square shape or a combination of square and rhombus shapes; however, the present disclosure is not limited thereto, and the configuration, shape, and layout of a single pixel PIX should be interpreted as one example.

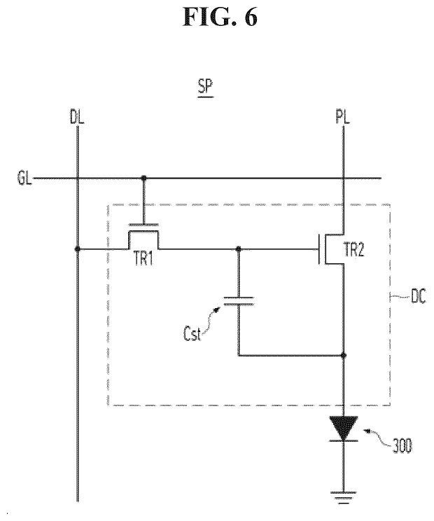

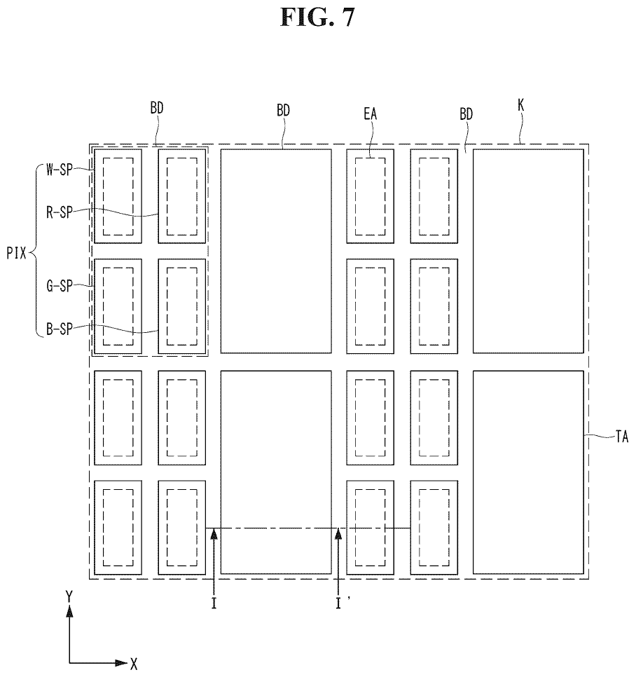

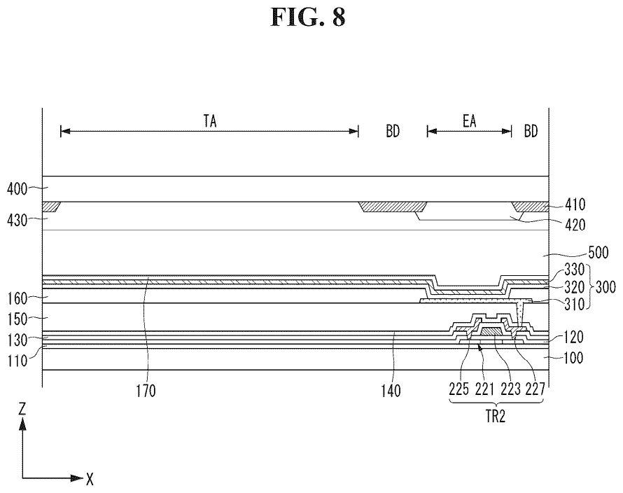

FIG. 6 is an example view showing a circuit of a subpixel according to one or more embodiments of the present disclosure. FIG. 7 is an enlarged example view of area K in FIG. 1. FIG. 8 is a sectional view taken along line I-I′ in FIG. 7.

As shown in FIG. 6, a single subpixel SP may display a specific color based on signals and voltage applied through signal and voltage lines GL, DL, and PL. The signal and voltage lines GL, DL, and PL may include a gate line GL for applying a gate signal, a data line DL for applying a data signal, and a power line PL for supplying a power voltage. The gate line GL may be connected to a gate drive circuit, the data line DL may be connected to a data drive circuit, and the power line PL may be connected to a power supply circuit.

The subpixel SP may include a pixel drive circuit DC connected to the signal and voltage lines GL, DL, and PL and a light emitting element 300 electrically connected to the pixel drive circuit DC. The pixel drive circuit DC may control the light emitting element 300 based on the signals and the voltage applied through the signal and voltage lines GL, DL, and PL. The pixel drive circuit DC may include a first thin film transistor TR1, a second thin film transistor TR2, and a storage capacitor Cst.

The first thin film transistor TR1 may transmit a data voltage to the storage capacitor Cst based on the gate signal. The storage capacitor Cst may transmit the data voltage to the second thin film transistor TR2. The second thin film transistor TR2 may generate a drive current based on the power voltage and the data voltage. The light emitting element 300 may emit light based on the drive current.

As shown in FIG. 7, a single pixel PIX disposed in the pixel area PA may include a white subpixel W-SP expressing white, a red subpixel R-SP expressing red, a green subpixel G-SP expressing green, and a blue subpixel B-SP expressing blue. The transmission area TA may be located between pixel areas PA. Meanwhile, FIG. 7 shows that one pixel area PA and one transmission area TA have a rectangular shape with the same area by way of example. However, this is merely one example, and the present disclosure is not limited thereto.

As shown in FIGS. 6, 7, and 8, an element substrate 100 may include glass or plastic. At least one insulating layer 110, 120, 130, 140, 150, and 160 configured to prevent unintended electrical connections may be located on the element substrate 100. For example, an element buffer layer 110, a gate insulating layer 120, an interlayer insulating layer 130, an element protection layer 140, an element planarization layer 150, and a bank insulating layer 160 may be located on the element substrate 100.

The element buffer layer 110 may be located on the element substrate 100. The gate insulating layer 120 may be located on the element buffer layer 110. The interlayer insulating layer 130 may be located on the gate insulating layer 120. The element protection layer 140 may be located on the interlayer insulating layer 130. The element planarization layer 150 may be located on the element protection layer 140.

For example, each of the element buffer layer 110, the gate insulating layer 120, the interlayer insulating layer 130, and the element protection layer 140 may be made of an inorganic insulating material, and the element planarization layer 150 may be made of an organic insulating material. However, this is merely one example, and the present disclosure is not limited thereto.

The second thin film transistor TR2 may be located between the element buffer layer 110 and the element planarization layer 150. The second thin film transistor TR2 may include a semiconductor layer 221, a gate electrode layer 223, a source electrode layer 225, and a drain electrode layer 227. The source electrode layer 225 and the drain electrode layer 227 may be connected respectively to a source area and a drain area of the semiconductor layer 221.

For example, the semiconductor layer 221 may be located between the element buffer layer 110 and the gate insulating layer 120, the gate electrode layer 223 may be located between the gate insulating layer 120 and the interlayer insulating layer 130, and the source electrode layer 225 and the drain electrode layer 227 may be located between the interlayer insulating layer 130 and the element protection layer 140. However, this is merely one example, and the present disclosure is not limited thereto.

The light emitting element 300 may be located between the element planarization layer 150 and a capping layer 170. The light emitting element 300 may include a first electrode layer 310, an emission layer 320, and a second electrode layer 330. The first electrode layer 310 may be connected to the drain electrode layer 227 of the second thin film transistor TR2. For example, the first electrode layer 310 may be located on the element planarization layer 150 and partitioned by the bank insulating layer 160, the emission layer 320 may be located on the first electrode layer 310, and the second electrode layer 330 may be located on the emission layer 320.

An adhesive layer 500 may be located on the capping layer 170, an upper planarization layer 430 may be located on the adhesive layer 500, a color filter layer 420 may be located on the upper planarization layer 430, and an encapsulation substrate 400 may be located on the color filter layer 420. The color filter layer 420 may be located so as to correspond to an emission area EA defined by the light emitting element 300.

The color filter layer 420 may be disposed so as to have colors distinguished per subpixel by a black matrix 410 disposed at a boundary portion BD. The emission area EA and the transmission area TA may also be distinguished by the black matrix 410 disposed at the boundary portion BD. Meanwhile, FIG. 8 shows an example in which a plurality of layers each made of an insulating material is located in the transmission area TA. However, this is merely one example, and the present disclosure is not limited thereto.

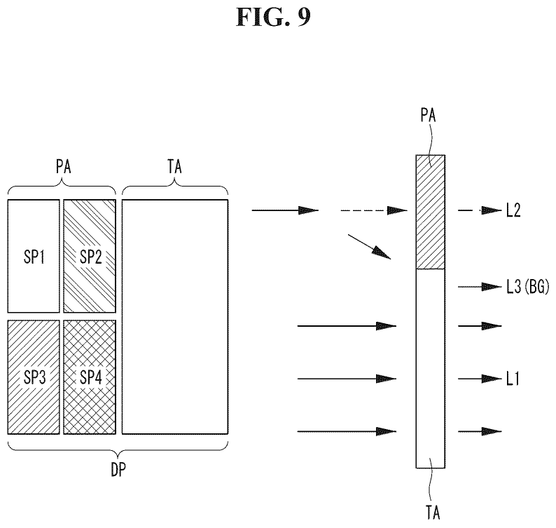

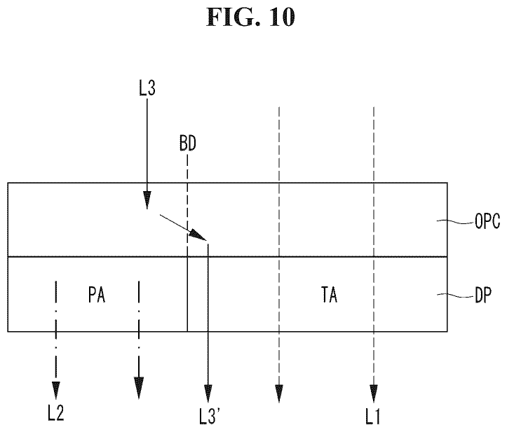

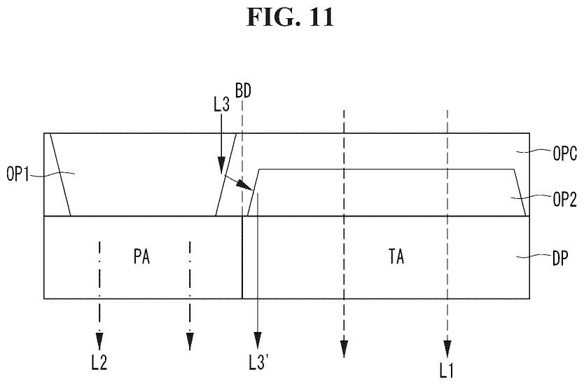

FIGS. 9 and 10 are views illustrating the characteristics of a display panel according to a first embodiment of the present disclosure. FIG. 11 is a sectional view showing an optical path control layer according to the first embodiment of the present disclosure.

As shown in FIG. 9, according to the first embodiment, the display panel DP may emit light L1 incident through a lower surface of the transmission area TA (or a rear surface of the display panel) directly through an upper surface of the transmission area TA (or a front surface of the display panel). The display panel DP may emit light L2 generated in the pixel area PA through an upper surface of the pixel area PA.

The transmission area TA emits (transmits) light L1 generated naturally, whereas the pixel area PA emits light L2 generated by the light emitting element. Therefore, when viewed from the transmission area TA, the pixel area PA may be defined as a light-shielding area that blocks light transmission.

According to the first embodiment, the display panel DP may change the path of light L3 incident through a lower surface of the pixel area PA and emit the light through the upper surface of the transmission area TA. The display panel DP may also make a part of the background BG present on the lower surface of the pixel area PA visible through the upper surface of the transmission area TA, based on the same method as used to change the path of light L3.

As shown in FIGS. 9 and 10, the display panel DP may include an optical path control layer OPC as a configuration for changing the path of light L3 incident vertically through the lower surface of the pixel area PA to a diagonal direction and a straight direction and emitting the light through the upper surface of the transmission area TA.

The optical path control layer OPC may be made of a resin in order to change the path of the incident light L3 based on a refractive index difference. The optical path control layer OPC may cause an optical illusion, such as the perception that the transmission area TA extends, by causing the light L3 incident through the lower surface of the pixel area PA to be emitted through the upper surface of the transmission area TA.

According to the first embodiment, the optical path control layer OPC may be located on a lower surface of the display panel DP, and may include a structure configured to change the path of light L3 incident vertically through the lower surface of the pixel area PA to a diagonal direction or a straight direction and to guide the light to the transmission area TA. The light L3 guided into the transmission area TA may be emitted from an area adjacent to the boundary portion BD by the structure included in the optical path control layer OPC. Hereinafter, the light incident through the optical path control layer OPC is indicated by L3, and the light emitted after the path thereof is changed by the optical path control layer OPC is indicated by L3′.

Meanwhile, the shape of the structure included in the optical path control layer OPC may vary depending on the structure of the pixel area PA and the structure of the transmission area TA. However, hereinafter, an example in which the pixel area PA and transmission area TA are implemented so as to have the structure shown in FIG. 7 will be described for ease of understanding.

As shown in FIG. 11, according to the first embodiment, the optical path control layer OPC may be located on the lower surface of the display panel DP. The optical path control layer OPC may include a first optical path control pattern layer OP1 (an incident structure layer) disposed in the pixel area PA and a second optical path control pattern layer OP2 (a reflective structure layer) disposed in the transmission area TA.

In the optical path control layer OPC, the space between the first optical path control pattern layer OP1 and the second optical path control pattern layer OP2 may be filled with an air layer or a resin layer having a different refractive index from the first optical path control pattern layer OP1 and the second optical path control pattern layer OP2. For example, the air layer filling the optical path control layer OPC may have a first refractive index, and the resin layer constituting the first optical path control pattern layer OP1 and the second optical path control pattern layer OP2 may have a second refractive index different from the first refractive index.

The first optical path control pattern layer OP1 and the second optical path control pattern layer OP2 may be partitioned by the boundary portion BD and disposed so as to be spaced apart from each other by a certain distance. The height of the second optical path control pattern layer OP2 may be less than that of the first optical path control pattern layer OP1; however, the present disclosure is not limited thereto.

Although not shown, the optical path control layer OPC may be protected by a protective layer. The protective layer may be made of a resin. When the protective layer is included, a different resin may be provided so as to have a refractive index difference between the protective layer and the optical path control layer OPC; however, the present disclosure is not limited thereto.

Each of the first optical path control pattern layer OP1 and the second optical path control pattern layer OP2 may have an equilateral trapezoidal shape based on the section where the pixel area PA and the transmission area TA are visible but may have a layout in which the positions of an upper surface and a lower surface are reversed. For example, the first optical path control pattern layer OP1 may be located with an upper surface thereof contacting the pixel area PA, whereas the second optical path control pattern layer OP2 may be located with a lower surface thereof contacting the transmission area TA.

For example, the light L3 incident vertically through the lower surface of the first optical path control pattern layer OP1 may be refracted diagonally by one surface of the first optical path control pattern layer OP1 (one of two non-parallel sides of the first optical path control layer, which is adjacent to the boundary portion) and guided to one surface of the second optical path control pattern layer OP2 (one of two non-parallel sides of the second optical path control layer, which is adjacent to the boundary portion). The light L3 guided to one surface of the second optical path control pattern layer OP2, after the path of the light L3′ is changed to a straight direction by refraction, may be emitted through the upper surface of the transmission area TA.

As such, the optical path control layer OPC may include a structure capable of changing the optical path of light radiated onto the lower surface of the pixel area PA and emitting the light to the transmission area TA, which may have various forms as follows.

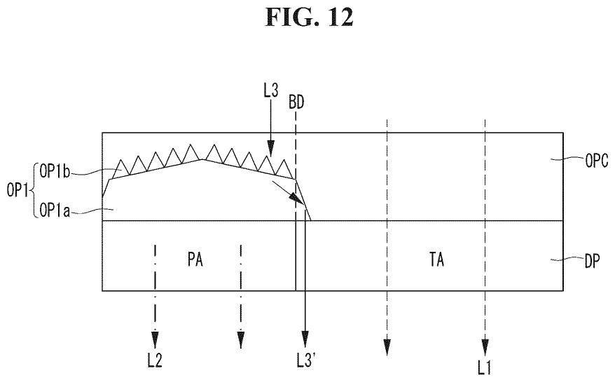

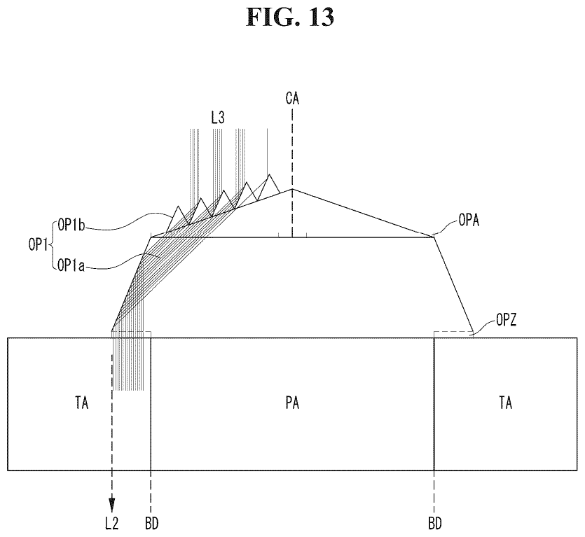

FIG. 12 is a sectional view showing an optical path control layer according to a second embodiment of the present disclosure. FIG. 13 is a view illustrating a first optical path control layer shown in FIG. 12 in more detail.

As shown in FIGS. 12 and 13, according to the second embodiment, the optical path control layer OPC may be located on the lower surface of the display panel DP. The optical path control layer OPC may include a first optical path control pattern layer OP1 disposed on the lower surface of the pixel area PA.

The space in the optical path control layer OPC other than the first optical path control pattern layer OP1 may be filled with an air layer or a resin layer having a different refractive index from the first optical path control pattern layer OP1. For example, the air layer filling the optical path control layer OPC may have a first refractive index, and the resin layer constituting the first optical path control pattern layer OP1 may have a second refractive index different from the first refractive index.

The first optical path control pattern layer OP1 may include a lower control pattern layer OP1a (a reflective structure layer) having a pentagonal shape based on the section where the pixel area PA and the transmission area TA are visible and an upper control pattern layer OP1b (an incident structure layer) located on the lower control pattern layer OP1a and having a scalene triangular shape.

Although not shown, the optical path control layer OPC may be protected by a protective layer. The protective layer may be made of a resin. When the protective layer is included, a different resin may be provided so as to have a refractive index difference between the protective layer and the optical path control layer OPC; however, the present disclosure is not limited thereto.

The lower control pattern layer OP1a may include a first surface (a lower surface) that is flat so as to have a larger area than the pixel area PA, a second surface (a first side surface) and a third surface (a second side surface) connected to one end and the other end of the first surface, respectively, having overlap zones OPZ partially overlapping the left and right transmission areas TA, and having the same slope, and a fourth surface (a first upper surface) and a fifth surface (a second upper surface) connected to the second surface and the third surface and connected to each other at a central area CA. The lower control pattern layer OP1a may have a left-right symmetrical shape with respect to the central area CA, and may have an isosceles triangular shape with the central area CA protruding upward due to the fourth surface and the fifth surface.

The upper control pattern layer OP1b may be disposed in plural on the fourth surface and fifth surface of the lower control pattern layer OP1a. The upper control pattern layer OP1b may include a first surface (a lower surface) disposed on the fourth surface (or the fifth surface) and a second surface (a first side surface) and a third surface (a second side surface) connected to one end of the first surface and the other end of the first surface, respectively, and forming a triangle together with the first surface. The upper control pattern layer OP1b may have a left-right symmetrical shape with respect to the central area CA, and may be disposed in the same number on the fourth surface and the fifth surface.

The lower control pattern layer OP1a may define a light control area OPA corresponding to a disposition area of the upper control pattern layer OP1b. The light control area OPA may not extend beyond the pixel area PA. Meanwhile, the overlap area OPZ and the light control area OPA may be separated from each other based on the boundary portion BD.

For example, the light L3 incident vertically through the upper control pattern layer OP1b may be refracted diagonally by internal total reflection at the second surface of the upper control pattern layer OP1b and guided to the second surface (the first side surface) of the lower control pattern layer OP1a. The light L3 guided to the second surface of the lower control pattern layer OP1a, after the path of the light L3′ is changed to a straight direction by refraction, may be emitted through the upper surface of the transmission area TA via the overlap zone OPZ.

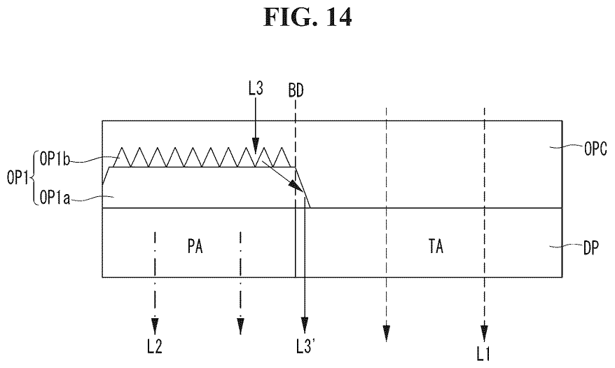

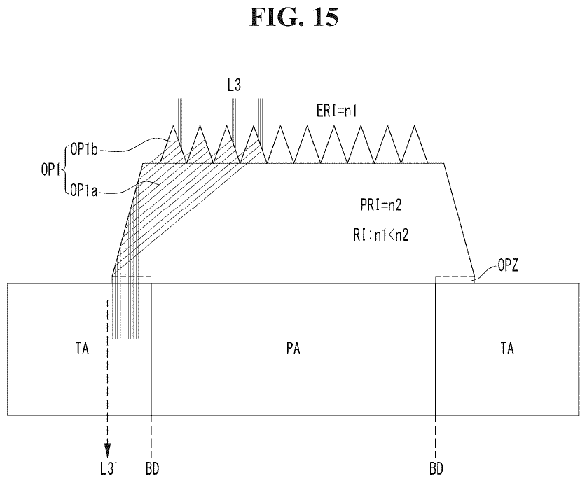

FIG. 14 is a sectional view showing an optical path control layer according to a third embodiment of the present disclosure. FIG. 15 is a view illustrating a first optical path control layer shown in FIG. 14 in more detail.

As shown in FIGS. 14 and 15, according to the third embodiment, the optical path control layer OPC may be located on the lower surface of the display panel DP. The optical path control layer OPC may include a first optical path control pattern layer OP1 disposed on the lower surface of the pixel area PA.

The space in the optical path control layer OPC other than the first optical path control pattern layer OP1 may be filled with an air layer or a resin layer having a different refractive index from the first optical path control pattern layer OP1. For example, the air layer filling the optical path control layer OPC may have a first refractive index, and the resin layer constituting the first optical path control pattern layer OP1 may have a second refractive index different from the first refractive index.

The first optical path control pattern layer OP1 may include a lower control pattern layer OP1a (a reflective structure layer) having an equilateral trapezoidal shape based on the section where the pixel area PA and the transmission area TA are visible and an upper control pattern layer OP1b (an incident structure layer) located on the lower control pattern layer OP1a and having an isosceles triangular shape.

Although not shown, the optical path control layer OPC may be protected by a protective layer. The protective layer may be made of a resin. When the protective layer is included, a different resin may be provided so as to have a refractive index difference between the protective layer and the optical path control layer OPC; however, the present disclosure is not limited thereto.

The lower control pattern layer OP1a may include a first surface (a lower surface) that is flat so as to have a larger area than the pixel area PA, a second surface (a first side surface) and a third surface (a second side surface) connected to one end and the other end of the first surface, respectively, having overlap zones OPZ partially overlapping the left and right transmission areas TA, and having the same slope, and a fourth surface (an upper surface) that is flat so as to be connected to the second surface and the third surface.

The upper control pattern layer OP1b may be disposed in plural on the fourth surface (the upper surface) of the lower control pattern layer OP1a. The upper control pattern layer OP1b may include a first surface (a lower surface) disposed on the fourth surface and a second surface (a first side surface) and a third surface (a second side surface) connected to one end of the first surface and the other end of the first surface, respectively, and forming a triangle together with the first surface.

Meanwhile, when an external refractive index is 1 (ERI=n1), the refractive index of the upper control pattern layer OP1b may be 2 (PRI=n2). Therefore, the relationship between the external refractive index and the refractive index of the upper control pattern layer OP1b may be implemented to satisfy RI:n1<n2; however, the present disclosure is not limited thereto. The lower control pattern layer OP1a and the upper control pattern layer OP1b may be made of resins having different refractive indices; however, the present disclosure is not limited thereto.

For example, the light L3 incident vertically through the upper control pattern layer OP1b may be refracted diagonally by internal total reflection at the second surface of the upper control pattern layer OP1b and guided to the second surface (the first side surface) of the lower control pattern layer OP1a. The light L3 guided to the second surface of the lower control pattern layer OP1a, after the optical path of the light L3′ is changed to a straight direction by refraction, may be emitted through the upper surface of the transmission area TA via the overlap zone OPZ.

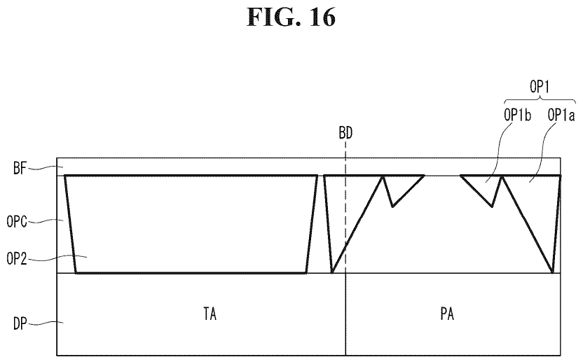

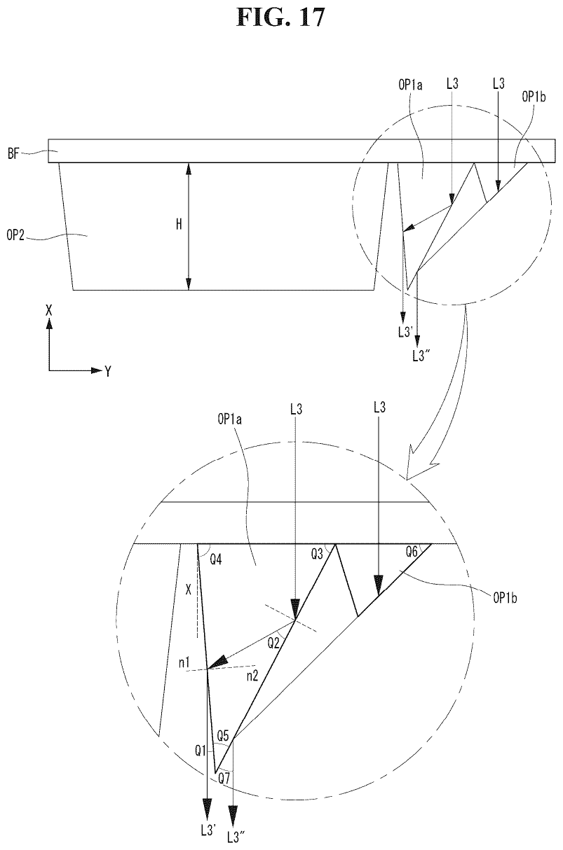

FIG. 16 is a sectional view showing an optical path control layer according to a fourth embodiment of the present disclosure. FIG. 17 is a view illustrating the optical path control layer shown in FIG. 16 in more detail.

As shown in FIGS. 16 and 17, according to the fourth embodiment, the optical path control layer OPC may be located on the lower surface of the display panel DP. The optical path control layer OPC may include an optical path control pattern layer OP1 disposed on the lower surface of the pixel area PA and a transmission portion flat layer OP2 disposed on the lower surface of the transmission area TA. The optical path control layer OPC may include a protective layer BF configured to effectively implement and protect the optical path control pattern layer OP1 and the transmission portion flat layer OP2. The space in the optical path control layer OPC other than the optical path control pattern layer OP1 may be filled with an air layer or a resin layer having a different refractive index from the optical path control pattern layer OP1.

The transmission portion flat layer OP2 may have a trapezoidal shape based on the section where the pixel area PA and the transmission area TA are visible. The transmission portion flat layer OP2 may include a first surface (a lower surface) that is flat, a second surface (a first side surface) and a third surface (a second side surface) connected to one end and the other end of the first surface, respectively, and a fourth surface (upper surface) connected to the second surface and the third surface and having a flat surface with a smaller area than the first surface.

The first surface of the transmission portion flat layer OP2 may abut the protective layer BF, and the fourth surface may abut the lower surface of the transmission area TA. The transmission portion flat layer OP2 may serve to protect a lamination surface (a bonding surface) between the optical path control layer OPC and the display panel DP while preventing the formation of an air layer Air in the transmission area TA.

The optical path control pattern layer OP1 may include a first side control pattern layer OP1a (a first structure layer) and a second side control pattern layer OP1b (a second structure layer) each having a scalene triangular shape based on the section where the pixel area PA and the transmission area TA are visible. Each of the first side control pattern layer OP1a and the second side control pattern layer OP1b may include a first surface (a lower surface) that is flat and a second surface (a first side surface) and a third surface (a second side surface) connected to one end and the other end of the first surface, respectively, and forming a triangle together with the first surface.

The first side control pattern layer OP1a and the second side control pattern layer OP1b may form a pair in the pixel area PA. The first side control pattern layer OP1a and the second side control pattern layer OP1b may be spaced apart from each other based on the central area CA of the pixel area PA and disposed opposite each other. That is, a first side control pattern layer OP1a and a second side control pattern layer OP1b may be located on one side of the central area CA of the pixel area PA, and a first side control pattern layer OP1a and a second side control pattern layer OP1b may be located on the other side of the central area CA of the pixel area PA.

The first surface of each of the first side control pattern layer OP1a and the second side control pattern layer OP1b may be located on the protective layer BF. The first side control pattern layer OP1a may be disposed at the boundary portion DB in an overlapping state so as to include an overlap area overlapping a part of the transmission area TA, and the second side control pattern layer OP1b may be disposed so as to be located in the pixel area PA. Meanwhile, while FIGS. 16 and 17 show that the first side control pattern layer OP1a and the second side control pattern layer OP1b are in contact with each other, the first side control pattern layer and the second side control pattern layer may be disposed spaced apart from each other.

The first side control pattern layer OP1a may be defined as a primary pattern layer capable of independently controlling the optical path, and the second side control pattern layer OP1b may be defined as an auxiliary pattern layer capable of assisting in controlling the optical path together with the first side control pattern layer OP1a. The height of the first side control pattern layer OP1a may be greater than the height of the second side control pattern layer OP1b.

For example, the first side control pattern layer OP1a may have a height similar to or equal to the height H of the transmission portion flat layer OP2. Meanwhile, although FIGS. 16 and 17 show that the first optical path control pattern layer OP1 includes both the first side control pattern layer OP1a and the second side control pattern layer OP1b, the second side control pattern layer OP1b may be omitted. However, hereinafter, an example including both the first side control pattern layer OP1a and the second side control pattern layer OP1b will be described for convenience of description.

For example, the light L3 incident vertically through the first side control pattern layer OP1a may be refracted diagonally by internal total reflection at the second surface (the first side surface) of the first side control pattern layer OP1a and guided to the third surface (the second side surface) of the first side control pattern layer OP1a. The light L3 guided to the third surface of the first side control pattern layer OP1a, after the path of the light L3′ is changed to a straight direction by refraction, may be emitted through the upper surface of the transmission area TA.

For example, the light L3 incident vertically through the second side control pattern layer OP1b may be refracted diagonally by internal total reflection at the second surface (the first side surface) of the second side control pattern layer OP1b and guided to the second surface (the first side surface) of the first side control pattern layer OP1a. The light L3 guided to the second surface of the first side control pattern layer OP1a, after the path of the light L3″ is changed to a straight direction by refraction, may be emitted through the upper surface of the transmission area TA.

Meanwhile, the first side control pattern layer OP1a and the second side control pattern layer OP1b may set a first angle Q1 to a seventh angle Q7 shown in FIG. 17 as in the following example in order to form identical conditions for the direction of the light L3 incident in the vertical direction (an incident light direction) and the direction of the emitted light L3′ and L3″ (an emitted light direction). However, in the following example, the pattern angle x defined by the direction of the vertically incident light L3 and the inclination of the third surface (the second side surface) of the first side control pattern layer OP1a is 3°, the external environment of the first side control pattern layer OP1a and the second side control pattern layer OP1b is formed by an air layer corresponding to the first refractive index (n1=0), and the internal environment of the first side control pattern layer OP1a and the second side control pattern layer OP1b is formed by a resin layer corresponding to the second refractive index (n2=1.6).

Under the above conditions, each of the first angle Q1 and fourth angle Q4 defining the emitted light at the first side control pattern layer OP1a may be 87° and may be set within a range of 90° to −3°. The second angle Q2 defining the reflected light from the first side control pattern layer OP1a may be 38.6193° relative to the third angle Q3, but this may be set according to Snell's law based on the first refractive index n1 and the second refractive index n2. The third angle Q3 defining the light incident onto the first side control pattern layer OP1a may be 65.8096°, but this may be set as the angle to allow the vertically incident light L3 to be incident at the second angle Q2. The fifth angle Q5 corresponding to the vertex angle defined by the second surface (the first side surface) and the third surface (the second side surface) of the first side control pattern layer OP1a may be 27.190°, but this may be set as an angle satisfying the third angle Q3. The sixth angle Q6 defining the light incident onto the second side control pattern layer OP1b may be 38.6193°, but this may be set to an angle capable of reflecting the vertically incident light L3 to the second surface (the first side surface) of the first side control pattern layer OP1a and then changing the same in the vertical direction. The seventh angle Q7 defining the light to be emitted vertically through the second surface (the first side surface) of the first side control pattern layer OP1a from the light reflected from the second side control pattern layer OP1b may be 24.1903°, but this may be set to an angle considering the third angle Q3 of the first side control pattern layer OP1a and the sixth angle Q6 of the second side control pattern layer OP1b.

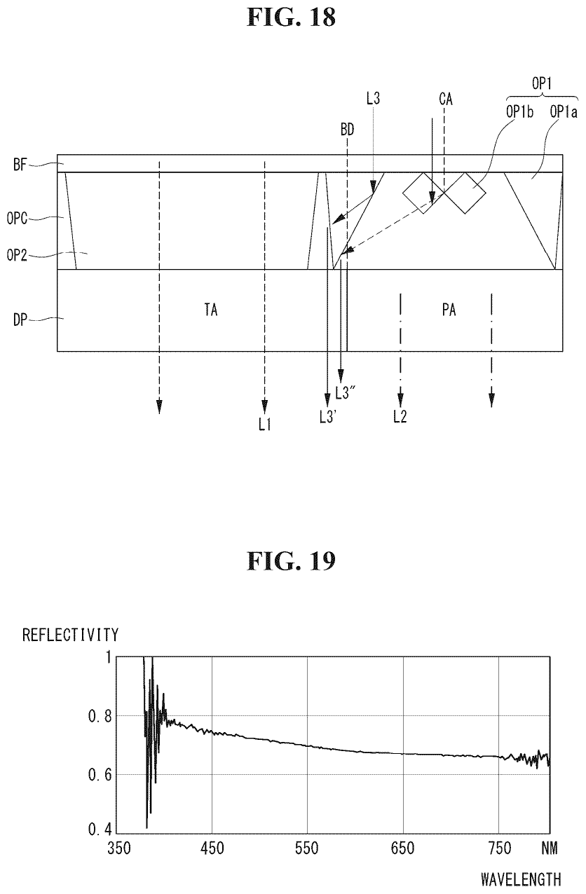

FIG. 18 is a sectional view showing an optical path control layer according to a modification of the fourth embodiment of the present disclosure.

As shown in FIG. 18, the modification of the fourth embodiment may be identical to the fourth embodiment except that the optical path control layer OPC is configured such that the second side control pattern layer OP1b has a rhombus shape and the second side control pattern layer OP1b disposed on one side and the second side control pattern layer OP1b disposed on the other side are symmetrical with respect to the central area CA of the pixel area PA while being in contact with each other at corners thereof.

FIG. 19 is a simulation result showing reflectivity of the second side control pattern layer for each reference wavelength of incident light according to one or more embodiments of the present disclosure.

As shown in FIG. 19 and Table 1 below, it can be seen that, when a second side control pattern layer OP1b, which can additionally control the optical path, is further included in the optical path control layer OPC, it is possible to increase the direct light by 10% and to reduce the scattered light by 17% compared to when the second side control pattern layer OP1b is absent. Therefore, when configuring the optical path control layer OPC, it may be more desirable to provide the second side control pattern layer OP1b.

TABLE 1

| | Without second side | With second side |
|---|---|---|
| Category | control pattern layer | control pattern layer |
| Total transmittance | 43.04 | 45.10 (105%) |
| Haze | 19.22 | 15.18 (79%) |
| Scattered light | 8.27 | 6.90 (83%) |
| Direct light | 34.77 | 38.20 (110%) |

In the second side control pattern layer shown in Table 1 above, the values in parentheses represent the percentage increase compared to the case without the second side control pattern layer.

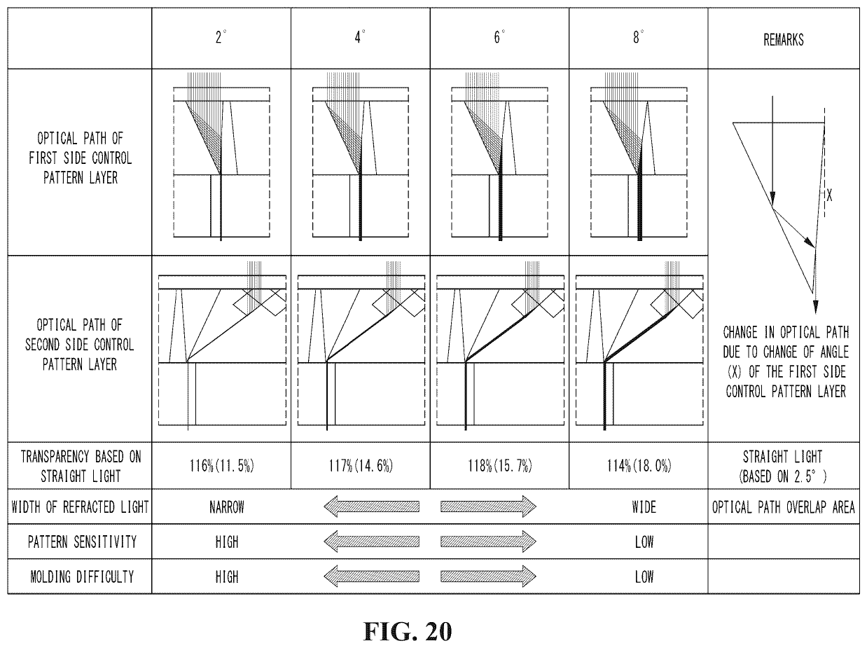

FIG. 20 is a simulation result illustrating changes in the optical path due to angle changes in a first side control pattern layer according to a modification of the fourth embodiment of the present disclosure. FIG. 20 is a simulation result obtained using an optical path control layer with a refractive index of 1.6.

As shown in FIG. 20, the angle x of the first side control pattern layer may be set to 2° and 8°. As the angle x of the first side control pattern layer decreases, transparency increases, but the width of refracted light may decrease and pattern sensitivity and molding difficulty may increase. Conversely, as the angle x of the first control pattern layer increases, transparency decreases, but the width of refracted light may increase and pattern sensitivity and molding difficulty may decrease. Therefore, the angle x of the first control pattern layer may be set considering the above factors.

As is apparent from the above description, the present disclosure has the effect that it is possible to improve transparency of a display panel (or minimize or at least decrease the reduction in brightness of the display panel) by changing the path of light proceeding to a light-shielding area of the display panel to a transmission area. In addition, the present disclosure has the effect that it is possible to induce an optical illusion, such as an improved aperture ratio, by allowing a part of the background disposed at a rear surface of the display panel to be visible through the transmission area.

What is claimed is:

1. A display device, comprising:
a display panel comprising a pixel area configured to generate light and a transmission area configured to transmit light;
a drive circuit configured to drive the display panel; and
an optical path control layer located at a rear surface of the display panel, wherein the optical path control layer is configured to guide a background of the pixel area or light to the transmission area.

2. The display device according to claim 1, wherein the optical path control layer comprises a structure configured to change a path of light incident vertically through a rear surface of the pixel area to a diagonal direction and a straight direction and to guide the light to the transmission area.

3. The display device according to claim 1, wherein the optical path control layer comprises:
an incident structure layer disposed to correspond to the pixel area; and
a reflective structure layer disposed to correspond to the transmission area.

4. The display device according to claim 3, wherein each of the incident structure layer and the reflective structure layer comprises an equilateral trapezoidal shape in which positions of an upper surface and a lower surface are reversed.

5. The display device according to claim 1, wherein the optical path control layer comprises:
a reflective structure layer disposed to correspond to the pixel area; and
a plurality of incident structure layers located on the reflective structure layer.

6. The display device according to claim 5, wherein the reflective structure layer comprises an overlap area overlapping a part of the transmission area.

7. The display device according to claim 5, wherein the reflective structure layer comprises a pentagonal shape, and
wherein each of the plurality of incident structure layers comprises a scalene triangular shape.

8. The display device according to claim 5, wherein the reflective structure layer comprises an equilateral trapezoidal shape, and
wherein each of the plurality of incident structure layers comprises an isosceles triangular shape.

9. The display device according to claim 1, wherein the optical path control layer comprises:
a structure layer disposed to correspond to the pixel area, and
a transmission portion flat layer disposed to correspond to the transmission area.

10. The display device according to claim 9, wherein the structure layer comprises a scalene triangular shape.

11. The display device according to claim 9, wherein the structure layer comprises a first structure layer and a second structure layer, each of the first structure layer and the second structure layer having a scalene triangular shape.

12. The display device according to claim 11, wherein the first structure layer comprises an overlap area overlapping a part of the transmission area.

13. The display device according to claim 11, wherein a height of the first structure layer is greater than a height of the second structure layer.

14. A display device, comprising:
a display panel comprising a pixel area configured to generate light and a transmission area configured to transmit light;
a drive circuit configured to drive the display panel; and
an optical path control layer located at a rear surface of the display panel, the optical path control layer configured to guide a background of the pixel area or light to the transmission area,
wherein the optical path control layer comprises a structure configured to change a path of light incident vertically through a rear surface of the pixel area and to guide the light to the transmission area.

15. The display device according to claim 14, wherein the optical path control layer further comprises a transmission portion flat layer disposed to correspond to the transmission area.

16. The display device according to claim 14, wherein the optical path control layer comprises:
an incident structure layer disposed to correspond to the pixel area; and
a reflective structure layer disposed to correspond to the transmission area.

17. The display device according to claim 14, wherein the optical path control layer comprises:
a reflective structure layer disposed to correspond to the pixel area; and
a plurality of incident structure layers located on the reflective structure layer.

18. A method of manufacturing a display device, the method comprising:
forming a display panel comprising a pixel area configured to generate light and a transmission area configured to transmit light;
forming an optical path control layer configured to guide a background of the pixel area or light to the transmission area; and
disposing the optical path control layer at a rear surface of the display panel, wherein the optical path control layer comprises a structure configured to change a path of light incident vertically through a rear surface of the pixel area to a diagonal direction and a straight direction and to guide the light to the transmission area.
